(19) United States
(12) Patent Application Publication
(10) Pub. No.: US 2025/0154378 A1
(43) Pub. Date: May 15, 2025

(54) DIE ATTACH ADHESIVES WITH TAILORABLE CHARACTERISTICS USING SELECTIVELY RELEASABLE ADDITIVES

(71) Applicant: Micron Technology, Inc., Boise, ID (US)

(72) Inventors: Ankur Harish Shah, Singapore (SG); Wen How Sim, Singapore (SG); Harjashan Veer Singh, San Jose, CA (US)

(21) Appl. No.: 18/926,872

(22) Filed: Oct. 25, 2024

Related U.S. Application Data
(60) Provisional application No. 63/597,583, filed on Nov. 9, 2023.

(51) Int. Cl. C09J 5/06; H01L 23/00

(52) U.S. Cl. CPC C09J 5/06; H01L 24/29; C09J 2203/322; H01L 24/32; H01L 2224/2929; H01L 2224/29298; H01L 2224/32225

(57) ABSTRACT

Die attach adhesives with tailorable characteristics using selectively releasable additives (and associated systems, devices, and methods) are disclosed herein. In one embodiment, a die attach adhesive includes (i) a primary material composition or resin and (ii) a structure within the primary material composition or resin. The die attach adhesive can further include one or more additives (a) contained within the structure and/or (b) mixed with the primary material composition or resin. The structure can be configured to release the one or more additives in response to a stimulus applied to the die attach adhesive. In some embodiments, the die attach adhesive can be a die attach film. In these and other embodiments, the structure can be a nanosphere. Additionally, or alternatively, the one or more additives can include a crosslink modifier, a viscosity modifier, and/or an anti-electrostatic discharge additive.

### CROSS-REFERENCE TO RELATED APPLICATION(S)

The present application claims priority to U.S. Provisional Patent Application No. 63/597,583, filed Nov. 9, 2023, the disclosure of which is incorporated herein by reference in its entirety.

### TECHNICAL FIELD

The present disclosure generally relates to semiconductor devices. For example, several embodiments of the present disclosure relate to die attach adhesives including structures (e.g., nanospheres) that, when selectively stimulated, release additives that alter one or more characteristics of the die attach adhesives.

### BACKGROUND

Die attach adhesives (e.g., die attach films, die attach pastes) are used to attach dies to substrates or other dies. For example, they are commonly employed when stacking chips in three-dimensional packaging. Die attach films are typically applied to dies at the wafer level before dicing. In other words, in comparison to die attach pastes, die attach films are typically preformed and attached to dies before those dies are singulated and attached to a substrate or another die. Die attach pastes, on the other hand, are typically dispensed on substrates shortly before singulated dies are attached to the substrates.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIGS. 1A-1C are partially schematic cross-sectional side views of a system including a die and a die attach adhesive configured in accordance with various embodiments of the present technology.

FIG. 2 is a flow diagram illustrating a method in accordance with various embodiments of the present technology.

FIG. 3 is a schematic view of a system that includes a semiconductor device configured in accordance with various embodiments of the present technology.

### DETAILED DESCRIPTION

Specific details of several embodiments of die attach adhesives with tailorable characteristics using selectively releasable additives (and associated apparatuses, systems, and methods) are described below. For the sake of clarity and example, the present technology is primarily described below in the context of using die attach films to attach dies to substrates. Die attach adhesives configured in accordance with other embodiments of the present technology, however, can include die attach pastes or other adhesives. Additionally, or alternatively, the present technology can be used to attach dies to other dies and/or to attach dies to one or more other structures.

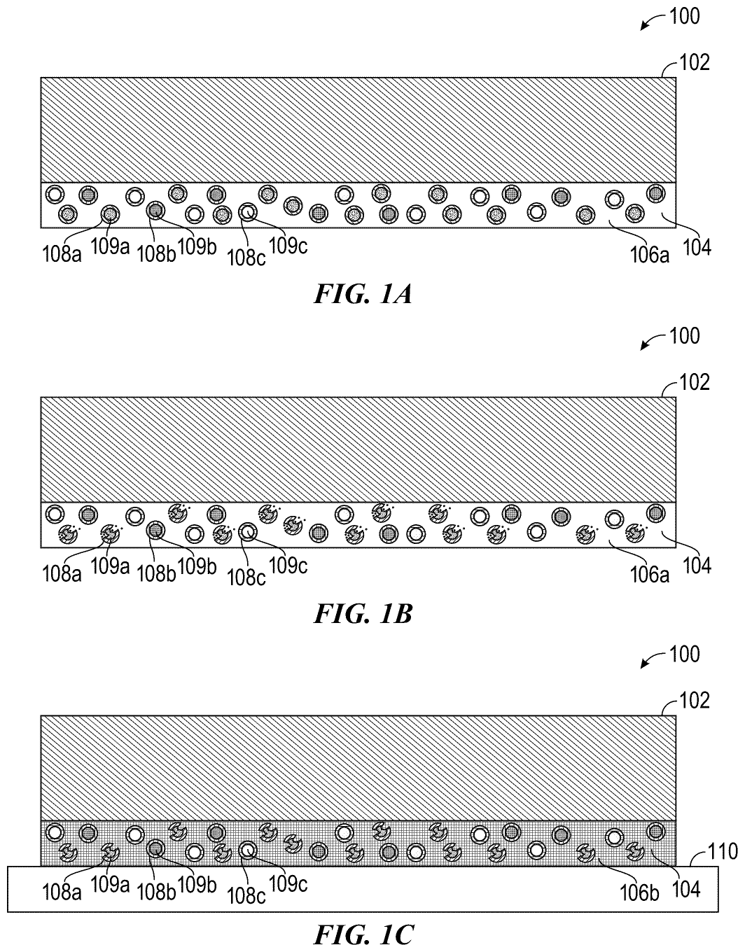

Specific details of several embodiments of the present technology are described herein with reference to FIGS. 1A-3. Although many of the embodiments are described herein with respect to die attach adhesives with tailorable characteristics using selectively releasable additives, other applications and other embodiments in addition to those described herein are within the scope of the present technology. Further, the embodiments of the present technology can have different configurations, components, and/or procedures than those shown or described herein, and/or that these and other embodiments can be without several of the configurations, components, and/or procedures shown or described herein without deviating from the present technology.

As used herein, the terms “vertical,” “lateral,” “upper,” “lower,” “top,” and “bottom” can refer to relative directions or positions of features in the semiconductor devices in view of the orientation shown in the Figures. For example, “bottom” can refer to a feature positioned closer to the bottom of a page than another feature. These terms, however, should be construed broadly to include semiconductor devices having other orientations, such as inverted or inclined orientations where top/bottom, over/under, above/below, up/down and left/right can be interchanged depending on the orientation.

Die attach adhesive is commonly employed to attach a die (e.g, a semiconductor die, a memory die) to a substrate or other die. Die attach films (DAFs) and die attach pastes are examples of die attach adhesives. DAFs are typically laminated on semiconductor wafers before the wafers are sawed into individual dies. DAF on a sawn die is then used to attach the die to a substrate or other die. Die attach pastes, on the other hand, are typically dispensed directly on a substrate or other die during the die attach process, and then a sawn die is placed on the dispensed die attach paste as part of the process of attaching the die to the substrate or other die. Although die attach pastes are most commonly used because of convenience (e.g., application timing and/or application flexibility), DAFs are regularly used because they can offer known die orientations (e.g., rotations, tilts), known bond line thicknesses, better bond line thickness uniformities, die attachments with little to no fillets, and/or die attachments with better die location accuracies.

During the die attach process, such as before, during or after die attachment and/or curing, it is not uncommon for issues (e.g., formation of voids, DAF delamination, non-uniform wetting) to arise. One current solution is to employ a die attach adhesive with specific properties (e.g., mechanical properties, viscoelastic properties, thermal history) that are expected to address (e.g., resolve, prevent) specific issues anticipated during the die attach process. As discussed above, however, a DAF is typically applied to dies at the wafer level (i) after the properties of the DAF are fixed based on the material composition or resin used to form the DAF and (ii) before a sawn die is attached to a substrate or other die. As such, if issues (unexpected or otherwise) arise during the die attach process that cannot be addressed by the fixed properties of the DAF, the die and DAF are scrapped, and another DAF with different properties must be employed. Employing another DAF with different properties commonly requires identification or development of a new DAF recipe or material that provides a desired set of properties that addresses issues observed during the die attach process. In other words, use of DAFs regularly results in assembly bottlenecks at the die attach stage. Similar problems can arise while using die attach pastes, such as during or after the curing stage.

To address these concerns, the present disclosure relates to die attach adhesives that include structures containing additives usable to alter or tailor one or more properties of the die attach adhesives. In one embodiment, a die attach adhesive (e.g., a DAF) includes a (i) primary material composition or resin and (ii) one or more structures (e.g., nanospheres) that each contain an additive. Examples of additives contained within one or more of the structures can include viscosity modifiers, crosslink enhancers, anti-electrostatic discharge (ESD) additives, or other suitable additives. The one or more structures can be selectively activated (e.g., using heat, light, ultrasound, or another suitable activation means) to selectively release the additive(s) such that the additive(s) are permitted to mix with the primary composition or resin and thereby alter one or more properties of the DAF.

In this manner, one or more properties of a die attach adhesive can be selectively tailored before, during, and/or after the die attachment and/or curing stages, such as to address one or more issues anticipated or observed before, during, and/or after the die attachment and/or curing stages. Thus, the present technology facilitates tuning one or more properties of a die attach adhesive to match specific desired functionality, facilitates large process and/or design windows, and permits different die attach adhesive responses using a single die attach adhesive.

FIG. 1A is a partially schematic cross-sectional side view of a system 100 configured in accordance with several embodiments of the present technology. As shown, the system 100 includes a die 102 and a die attach adhesive 104. The die 102 can be a semiconductor die (e.g., a memory die, etc.). The die attach adhesive 104 can be used to attach the die 102 to another structure 110 (FIG. 1C), such as a substrate or another die.

For the sake of example, the die attach adhesive 104 is illustrated as a DAF. In other embodiments, the die attach adhesive 104 can be a die attach paste or other suitable adhesive. In embodiments in which the die attach adhesive 104 is a DAF, the die attach adhesive 104 can be laminated onto the die 102 at the wafer-stage before the wafer is sawn to produce the system 100 shown. In other embodiments, the die attach adhesive 104 can be applied to or otherwise interfaced with the die 102 at a different stage. For example, the die attach adhesive 104 can be applied to (e.g., laminated on) the die 102 after the die 102 is singulated. As another example, the die attach adhesive 104 can be dispensed on a substrate (e.g., on the structure 110 of FIG. 1C), another die, or another structure. Thereafter, the die 102 can be placed on the die attach adhesive 104 as part of the process of attaching the die 102 to the substrate, other die, or other structure.

In the illustrated embodiment, the die attach adhesive 104 includes a first primary material composition or resin 106a. As discussed in greater detail below, the die attach adhesive 104 can include a first set of properties (e.g., material properties) that is based at least in part on the first primary material composition/resin 106a. For example, the first set of properties can include first mechanical properties, first viscoelastic properties, a first thermal history, first anti-electrostatic discharge (“anti-ESD”) properties, etc.

As shown in FIG. 1A, the die attach adhesive 104 additionally includes a plurality of structures 108 (identified individually in FIG. 1A as structure 108a, structure 108b, and structure 108c) within the primary material composition/resin 106a that each releasably contain a corresponding additive 109 (identified individually in FIG. 1A as additive 109a, additive 109b, and additive 109c). In the illustrated embodiment, each of the structures 108 are spherical. In some embodiments, the spherical structures 108 can be nanospheres. In other embodiments of the present technology, one or more of the structures 108 can have a different construction, including a non-spherical construction.

The additives 109 can include solids and/or liquids that can be used to modify one or more properties of the die attach adhesive 104. More specifically, as discussed in greater detail below, each of the structures 108 can be selectively activated (e.g., stimulated) to rupture, break, or otherwise release the corresponding additive 109 contained within the structure 108. As the corresponding additive 109 is released, the additive 109 can mix with the first primary material composition/resin 106a of the die attach adhesive 104 and modify (e.g., alter, lessen, enhance) one or more properties of the die attach adhesive 104.

For example, the structure 108a shown in FIG. 1A can include a liquid or solid additive 109a that includes a crosslink modifier. Continuing with this example, when the additive 109a is released from the structure 108a, the additive 109a can mix with the first primary material composition/resin 106a of the die attach adhesive 104 and thereby modify (e.g., enhance or lessen) mechanical properties of the die attach adhesive 104. As a specific example, the additive 109a can include a crosslink enhancer that is usable, when released from the structure 108a, to provide additional crosslinking molecules or crosslink sites within the die attach adhesive 104 that can increase the post cure tensile strength or modulus of the die attach adhesive 104. Enhancing the post cure tensile strength or modulus of the die attach adhesive 104 can decrease the probability of thin die warpage, facilitate larger overhangs of dies in a multi-die stack, and/or improve damping coefficients such that stress can be better transferred from the die 102 to the die attach adhesive 104 and thereby lessen the probability of die crack post encapsulant. Examples of crosslink modifier additives 109a that can be included in one or more structures 108a of the die attach adhesive 104 include liquid polymers (e.g., liquid polymers with low molecular weights, such as polyethylene glycols) with crosslinking functional groups (e.g., acrylates, epoxy diazirine, azide, etc.).

As another example, the structure 108b shown in FIG. 1A can include a liquid or solid additive 109b that includes a viscosity modifier. Continuing with this example, when the additive 109b is released from the structure 108b, the additive 109b can mix with the first primary material composition/resin 106a of the die attach adhesive 104 and thereby modify (e.g., increase or lessen) the viscosity of the die attach adhesive 104. As specific example, the additive 109b can include a viscosity modifier that is usable, when released from the structure 108b, to lessen the viscosity of the die attach adhesive 104 such that wetting of the die attach adhesive 104 with a substrate, another die, and/or another structure can be improved. Examples of viscosity modifier additives 109b that can be included in one or more structures 108b of the die attach adhesive 104 include liquid polymers (e.g., liquid polymers with low molecular weights, such as dendrimers) or linear chain polyethylene-glycols (e.g., linear chain polyethylene-glycols (i) with low molecular weights and/or (ii) with or without function groups).

As still another example, the structure 108c shown in FIG. 1A can include a liquid or solid additive 109c that includes an anti-ESD additive. Continuing with this example, when the additive 109c is released from the structure 108c, the additive 109c can mix with the first primary material composition/resin 106a of the die attach adhesive 104 and thereby modify (e.g., increase or lessen) anti-ESD properties of the die attach adhesive 104. As a specific example, the additive 109c can include an anti-ESD additive that is usable, when released from the structure 108c, to increase the anti-ESD properties of the die attach adhesive 104 to prevent or inhibit ESD within or through the die attach adhesive 104. Examples of anti-ESD modifier additives 109c that can be included in one or more structures 108c of the die attach adhesive 104 include conductive or semiconductive fillers, such as black carbon, two-dimensional (2D) graphene, carbon nanotubes, etc.

Other additives in addition to or in lieu of crosslink modifiers, viscosity modifiers, and/or anti-ESD additives can be included within one or more structures 108 of the die attach adhesive 104 in other embodiments of the present technology. Examples of other additives that can be releasably contained within one or more structures 108 of the die attach adhesive 104 include compressive strength modifiers, durability modifiers, flexural strength modifiers, thermal conductivity modifiers, thermal diffusivity modifiers, electrical resistivity modifiers, corrosion resistance modifiers, and/or one or more other suitable modifiers, such as metallic nanoparticles (e.g., formed of or including gold), metallic nanotubes (e.g., formed of or including copper or tungsten), or organic additives (e.g., dendrimers and/or long chain polymers such as polycaptolactone, polyvinylchloride, etc.).

The structures 108 shown in FIG. 1A are each formed of a material that, when selectively activated, rupture, break, or otherwise release the corresponding additive 109 contained within the structure 108. For example, one or more of the structures 108 can be formed of a material that, when exposed to a specific temperature, ruptures, breaks, or otherwise allows the corresponding additive(s) 109 to exit the one or more structures 108. Continuing with this example, the additive(s) 109 contained within the one or more structures 108 can be selectively released by exposing the one or more structures 108 to the specific temperature, such as before, during, or after the die attach and/or curing stages. In some embodiments, the specific temperature can be a temperature that is greater than temperatures that are typically used during the die attach and/or curing stages. Examples of materials that can be used to form one or more of such structures 108 include carriers formed of or including polycaprolactone (e.g., N-isopropyl acrylamide) or polypyrrole that, when subjected to specific or higher temperatures, release an encased additive 109 (e.g., via temperature-dependent diffusion or rupture).

As another example, one or more of the structures 108 can be formed of a material that, when exposed to light of a specific wavelength, ruptures, breaks, or otherwise allows the corresponding additive(s) 109 to exit the one or more structures 108. Continuing with this example, the additive(s) 109 contained within the one or more structures 108 can be selectively released by exposing the one or more structures 108 to the specific wavelength of light, such as before, during, or after the die attach and/or curing stages. Examples of materials that can be used to form one or more of such structures 108 include carriers formed of or including polypyrrole (IR) or upconverting nanoparticles (UCNP) that, when subjected or exposed to (e.g., specific wavelengths of) light, rupture to allow encased additives 109 to leach out and/or get activated to generate reactive species (e.g., that can further accelerate crosslinking or dominant reactive moieties of the die attach adhesive 104).

As still another example, one or more of the structures 108 can be formed of a material that, when exposed to (e.g., a specific frequency of) ultrasound energy, ruptures, breaks, or otherwise allows the corresponding additive(s) 109 to exit the one or more structures 108. Continuing with this example, the additive(s) 109 contained within the one or more structures 108 can be selectively released by subjecting the one or more structures 108 to (e.g., the specific frequency of) ultrasound energy, such as before, during, or after the die attach and/or curing stages. Examples of materials that can be used to form one or more of such structures 108 include mesoporus silica capped with thin layers of polymers (e.g., cellulose) that, when subjected to (e.g., specified frequencies of) ultrasound energy, rupture and release encased additives 109 through porous openings.

In the illustrated embodiment, each of the structures 108a-108 are formed of a different material. For example, the structure 108a can be formed of a first material that is configured to rupture, break, or otherwise release the additive 109a when the structure 108a is subjected to a specific temperature; the structure 108b can be formed of a second material that is configured to rupture, break, or otherwise release the additive 109b when the structure 108b is exposed to a specific wavelength of light; and/or the structure 108c can be formed of a third material that is configured to rupture, break, or otherwise release the additive 109c when the structure 108c is subjected to (e.g., a specific frequency of) ultrasound energy.

As another example, the structure 108a can be formed of a first material that is configured to release the additive 109a when the structure 108a is subjected to a first specific temperature; the structure 108b can be formed of a second material that is configured to release the additive 109b when the structure 108b is subjected to a second specific temperature; and/or the structure 108c can be formed of a third material that is configured to release the additive 109c when the structure 108c is subjected to a third specific temperature. The first temperature, the second temperature, and/or the third temperature can be different from one another.

As still another example, the structure 108a can be formed of a first material that is configured to release the additive 109a when the structure 108a is subjected to a first specific wavelength of light; the structure 108b can be formed of a second material that is configured to release the additive 109b when the structure 108b is subjected to a second specific wavelength of light; and/or the structure 108c can be formed of a third material that is configured to release the additive 109c when the structure 108c is subjected to a third specific wavelength of light. The first wavelength, the second wavelength, and/or the third wavelength can be different from one another.

As yet another example, the structure 108a can be formed of a first material that is configured to release the additive 109a when the structure 108a is subjected to a first specific frequency of ultrasound energy; the structure 108b can be formed of a second material that is configured to release the additive 109b when the structure 108b is subjected to a second specific frequency of ultrasound energy; and/or the structure 108c can be formed of a third material that is configured to release the additive 109c when the structure 108c is subjected to a third specific frequency of ultrasound energy. The first frequency, the second frequency, and/or the third frequency can be different from one another.

In other embodiments of the present technology, the structure 108a, the structure 108b, and/or the structure 108c can be formed of a same or similar material. For example, two or more of the structures 108a-108c can be formed of a same material that can be activated in response to a stimulus (e.g., a temperature, a wavelength of light, and/or a frequency of ultrasound energy). Continuing with this example, when the structures 108a-108c are exposed to the stimulus, the two or more of the structures 108a-108c can both be activated and rupture, break, or otherwise release the corresponding additives 109a, 109b, and/or 109c contained within the two or more of the structures 108a-108c.

Additionally, or alternatively, the structure 108a, the structure 108b, and/or the structure 108c can be formed of a same or similar material but include varying characteristics. For example, the structure 108a and the structure 108b can both be formed of a first material, but the structure 108a can have a first set of characteristics (e.g., wall thickness, size, internal volume, shape, density, etc.) that differs from a second set of characteristics (e.g., wall thickness, size, internal volume, shape, density, etc.) of the structure 108b. In some embodiments, the different characteristics can have different responses to a same stimulus. Thus, the structure 108a can rupture, break, or otherwise release the additive 109a in response to a first stimulus in a manner that differs from the manner in which the structure 108b ruptures, breaks, or otherwise releases the additive 109b in response to the first stimulus and/or a second stimulus.

In these and still other embodiments, other materials in addition to or in lieu of materials that can be selectively activated using temperature, light, and/or ultrasound can be used to form one or more structures 108 in other embodiments of the present technology. For example, one or more materials that can rupture, break, or otherwise release an additive in response to electrical, magnetic, vibratory, pressure, chemical, and/or other suitable stimuli, can be used to form one or more structures 108 in various embodiments of the present technology.

FIG. 1B is a partially schematic cross-sectional side view of the system 100 of FIG. 1A when the structures 108 of the die attach adhesive 104 are selectively subjected to a stimulus. As shown, when the structures 108 of the die attach adhesive 104 are subjected to a stimulus (e.g., a specific temperature, a specific wavelength of light, a specific frequency of ultrasound energy, etc.), the structure 108a and other similar structures included in the die attach adhesive 104 are activated and rupture, break, or otherwise release a corresponding additive 109a (e.g., a crosslink modifier, a viscosity modifier, an anti-ESD additive, etc.) such that the corresponding additive 109a is permitted to mix with the first primary material composition/resin 106a of the die attach adhesive 104. In the illustrated embodiment, the structures 108b and 108c (and other similar structures included in the die attach adhesive 104) are not activatable in response to the selected stimulus (but may be activated in response to one or more different stimuli). Thus, corresponding additives 109b and 109c (e.g., crosslink modifiers, viscosity modifiers, anti-ESD additives, etc.) are not released from the structures 108b and 108c (and the other similar structures) when subjected to the selected stimulus, such that the corresponding additives 109b and 109c are prevented from mixing with the first primary material composition/resin 106a of the die attach adhesive 104 and/or the released additive 109a.

FIG. 1C is a partially schematic cross-sectional side view of the system 100 of FIGS. 1A and 1B after the additive 109a mixes with the first primary material composition/resin 106a (FIGS. 1A and 1B) of the die attach adhesive 104 and after the die attach adhesive 104 is used to attach the die 102 to a structure 110 (e.g., before, during, or after the curing stage). As shown, mixing of the additive 109a released from the structure 108a and other similar structures included within the die attach adhesive 104 can alter the first primary material composition/resin 106a of the die attach adhesive to a second primary material composition/resin 106b. Altering the first primary material composition/resin 106a to the second primary material composition/resin 106b can alter one or more properties of the die attach adhesive. For example, as discussed above, the die attach adhesive 104 can include a first set of properties (e.g., material properties) prior to release of the additive 109a. The first set of properties can be based at least in part on the first primary material composition/resin 106a. After the additive 109a is released and mixes with the first primary material composition/resin 106a such that the first primary material composition/resin 106a is altered to the second primary material composition/resin 106b, the die attach adhesive 104 can include a second set of properties (e.g., material properties) that is different from the first set. As a specific example, when the additive 109a includes a crosslink modifier, the second set of properties can include one or more mechanical properties (e.g., a stronger post cure tensile strength/modulus) based at least in part on the second primary material composition/resin 106b that are different from one or more corresponding mechanical properties of the first set. As another example, when the additive 109a includes a viscosity modifier, the second set of properties can include one or more viscoelastic properties (e.g., a lower viscosity) based at least in part on the second primary material composition/resin 106b that are different from one or more corresponding viscoelastic properties of the first set. As still another example, when the additive 109a includes an anti-ESD additive, the second set of properties can include one or more anti-ESD properties based at least in part on the second primary material composition/resin 106b that are different from one or more corresponding anti-ESD of the first set.

In this manner, one or more additives 109 can be selectively released from the corresponding structures 108 by selectively activating the corresponding structures 108 with one or more specific stimuli. As the one or more additives 109 are released from the corresponding structures 108, the one or more additives 109 can mix with the primary material composition/resin 106 of the die attach adhesive 104 to alter one or more properties of the die attach adhesive. In other words, one or more characteristics of the die attach adhesive 104 can be selectively altered. Thus, one or more properties of a die attach adhesive 104 configured in accordance with the present technology can be selectively tailored (e.g., to address one or more observed or anticipated issues) before, during, or after the die attach and/or curing stages.

Although shown with a specific number of structures 108 and additives 109 in FIGS. 1A-IC, die attach adhesive 104 configured in accordance with other embodiments of the present technology can include a greater or lesser number of structures 108 and/or additives 109. Additionally, or alternatively, although shown with three different structures 108 and additives 109 in FIGS. 1A-IC, die attach adhesives configured in accordance with other embodiments of the present technology can include a greater or lesser number of different structures 108 and/or additives 109. For example, all of the structures 108 included in a die attach adhesive 104 can be uniform, include the same characteristics, and/or activate in response to a same stimulus. Continuing with this example, each of the structures 108 included in the die attach adhesive 104 can contain a same additive 109, or at least a subset of the structures 108 can include an additive 109 that differs from an additive 109 contained within another structure 108 of the die attach adhesive 104. Furthermore, although the system 100 is shown in FIG. 1C with a die attach adhesive 104 that has a second primary material composition/resin 106b after the additive 109a mixes with the first primary material composition/resin 106a (FIGS. 1B and 1C), the primary material composition/resin 106 of a die attach adhesive 104 can, in other embodiments, remain unchanged after mixing with one or more additives even though one or more properties of die attach adhesive 104 may be altered via the mixing.

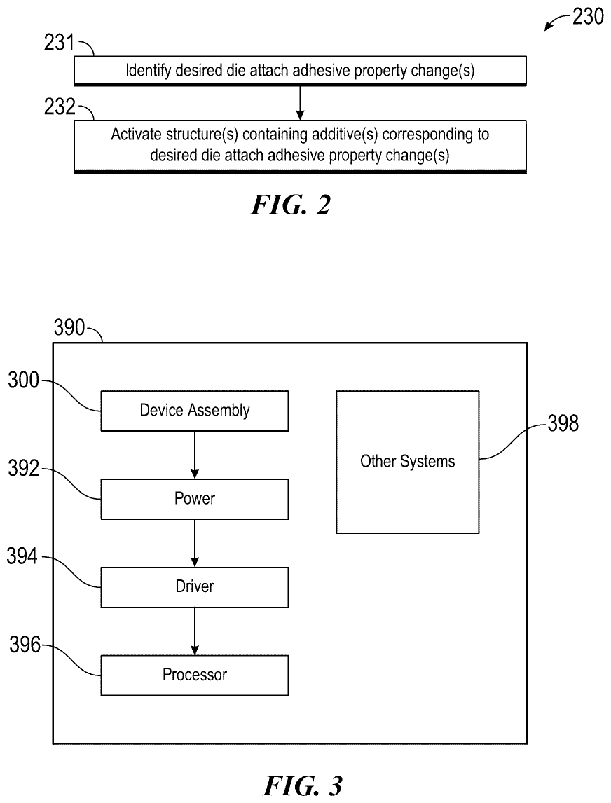

FIG. 2 is a flow diagram illustrating method 230 in accordance with various embodiments of the present technology. In some embodiments, the method 230 can be employed to selectively tailor one or more characteristics or properties of a die attach adhesive, such as the dic attach adhesive 104 of FIGS. 1A-IC. The method 230 is illustrated as a series of steps or blocks 231 and 232. All or a subset of one or more of the steps 231 and 232 of the method 230 can be executed in accordance with the discussion above.

The method 230 begins at block 231 by identifying one or more desired changes to one or more properties of a die attach adhesive. The die attach adhesive can be usable to attach a die to a substrate, another die, or another structure. In these and other embodiments, the die attach adhesive can be or include a DAF or a die attach paste.

Identifying the one or more desired changes can include observing or anticipating one or more issues during a die attach stage and/or a curing stage. The one or more desired changes can correspond to changes in the one or more properties that are expected to address the one or more observed or anticipated issues. Additionally, or alternative, identifying the one or more desired changes can include identifying one or more desired properties of the die attach adhesive before, during, and/or after the die attach stage and/or the curing stage.

At block 232, the method 230 continues by activating one or more structures included in the die attach adhesive. The one or more structures can contain one or more additives that correspond to the one or more desired changes to the one or more properties of the die attach adhesive. For example, the one or more structures can contain a crosslink modifier to alter one or more mechanical properties of the die attach adhesive, a viscosity modifier to alter one or more viscoelastic properties of the die attach adhesive, and/or an anti-ESD additive to alter one or more anti-ESD properties of the die attach adhesive.

Activating the one or more structures can include subjecting the one or more structures to one or more stimuli that causes the one or more structures to rupture, break, or otherwise release the one or more additives contained within the one or more structures. For example, activating the one or more structures can include applying the one or more stimuli to the one or more structures. The one or more stimuli can include a specific temperature or specific range of temperatures, light, a specific wavelength or range of wavelengths of light, ultrasound energy, a specific frequency or range of frequencies of ultrasound energy, and/or other suitable stimuli. Additionally, or alternatively, activating the one or more structures can include releasing or otherwise facilitating the one or more additives contained within the one or more structures to mix with a primary material composition or resin of the die attach adhesive (e.g., such that the one or more properties of the die attach adhesive are altered in accordance with the one or more desired changes from block 231).

Although the steps of the method 230 are discussed and illustrated in a particular order, the method 230 is not so limited. In other embodiments, the method 230 can be performed in a different order. In these and other embodiments, any of the steps of the method 230 can be performed before, during, and/or after any of the other steps of the method 230. Furthermore, the method 230 can be altered and still remain within these and other embodiments of the present technology. For example, one or more steps (e.g., block 231) of the method 230 can be omitted. As another example, one or more steps (e.g., block 231 and/or block 232) can be repeated in some embodiments.

Any one of the semiconductor devices described above with reference to FIGS. 1A-2 can be incorporated into any of a myriad of larger and/or more complex systems, a representative example of which is system 390 shown schematically in FIG. 3. The system 390 can include a semiconductor die assembly 300, a power source 392, a driver 394, a processor 396, and/or other subsystems or components 398. The semiconductor die assembly 300 can include semiconductor devices with features generally similar to those of the semiconductor devices described above. The resulting system 390 can perform any of a wide variety of functions, such as memory storage, data processing, and/or other suitable functions. Accordingly, representative systems 390 can include, without limitation, hand-held devices (e.g., mobile phones, tablets, digital readers, and digital audio players), computers, and appliances. Components of the system 390 may be housed in a single unit or distributed over multiple, interconnected units (e.g., through a communications network). The components of the system 390 can also include remote devices and any of a wide variety of computer readable media.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A die attach adhesive, comprising:
a primary material composition or resin;
a structure within the primary material composition or resin; and
one or more additives contained within the structure,
wherein the structure is configured to release the one or more additives in response to a stimulus applied to the die attach adhesive.

2. The die attach adhesive of claim 1, wherein the one or more additives include a crosslink modifier configured, when mixed with the primary material composition or resin, to modify a post cure tensile strength or modulus of the die attach adhesive.

3. The die attach adhesive of claim 1, wherein the one or more additives include a viscosity modifier configured, when mixed with the primary material composition or resin, to modify a viscosity of the die attach adhesive.

4. The die attach adhesive of claim 1, wherein the one or more additives include an anti-electrostatic discharge (ESD) additive configured, when mixed with the primary material composition or resin, to modify one or more ESD properties of the die attach adhesive.

5. The die attach adhesive of claim 1, wherein the stimulus includes a specific temperature such that the structure is configured to release the one or more additives when the structure reaches the specific temperature.

6. The die attach adhesive of claim 1, wherein the stimulus includes a specific wavelength of light such that the structure is configured to release the one or more additives when the structure is exposed to the specific wavelength of light.

7. The die attach adhesive of claim 1, wherein the stimulus includes ultrasound energy such that the structure is configured to release the one or more additives when the structure is subjected to ultrasound energy.

8. The die attach adhesive of claim 1, wherein:
the primary material composition or resin is a first primary material composition or resin;
the die attach adhesive includes a first set of material properties that is based at least in part on the first primary material composition or resin;
the one or more additives are configured, when released from the structure, to mix with the first primary material composition or resin to produce a second primary material composition or resin such that the die attach adhesive includes a second set of material properties that is based at least in part on the second primary material composition or resin; and
the second set of material properties is different from the first set of material properties.

9. The die attach adhesive of claim 1, wherein:
the is a first structure;
the one or more additives include a first additive contained within the first structure;
the die attach adhesive further comprises a second structure within the primary material composition or resin that is different from the first structure; and
the one or more additives include a second additive contained within the second structure.

10. The die attach adhesive of claim 9, wherein:
the stimulus is a first stimulus;
the second structure is configured to release the second additive in response to a second stimulus applied to the die attach adhesive; and
the second stimulus is different from the first stimulus.

11. The die attach adhesive of claim 10, wherein the second structure is configured such that the second structure does not release the second additive in response to the first stimulus applied to the die attach adhesive.

12. The die attach adhesive of claim 10, wherein:
the first stimulus is a first temperature and the second stimulus is a second temperature different from the first temperature;
the first stimulus is a first wavelength of light and the second stimulus is a second wavelength of light different from the first wavelength of light; or
the first stimulus is a first frequency of ultrasound energy and the second stimulus is a second frequency of ultrasound energy different from the first frequency.

13. The die attach adhesive of claim 1, wherein the structure is a nanosphere.

14. The die attach adhesive of claim 1, wherein the die attach adhesive is a die attach film (DAF).

15. A die attach adhesive, comprising:
a primary material composition or resin;
a ruptured structure within the primary material composition or resin,
wherein the primary material composition or resin is formed at least in part of one or more additives released from the ruptured structure.

16. The die attach adhesive of claim 15, wherein the one or more additives includes a crosslink modifier, a viscosity modifier, an anti-electrostatic discharge (ESD) additive, or any combination thereof.

17. The die attach adhesive of claim 15, further comprising an unruptured structure within the primary material composition or resin, wherein the unruptured structure contains an additive that is configured, when released from the unruptured structure, to alter one or more material properties of the die attach adhesive.

18. The die attach adhesive of claim 17, wherein:
the ruptured structure is formed of a first material; and
the unruptured structure is formed of a second material that is different from the first material.

19. A system, comprising:
a die;
a substrate; and
a die attach adhesive attaching the die to a surface of the substrate, wherein the die attach adhesive includes—
a primary material composition or resin; and
a ruptured structure within the primary material composition or resin.

20. The system of claim 19, wherein the primary material composition or resin of the die attach adhesive is formed at least in part of one or more additives released from the ruptured structure.
